(19) United States
(12) Patent Application Publication
(10) Pub. No.: US 2007/0187776 A1
(43) Pub. Date: Aug. 16, 2007

(54) SEMICONDUCTOR DEVICE AND METHOD OF FABRICATING THE SAME

(75) Inventor: Gen Sasaki, Kanagawa (JP)

Correspondence Address: FOLEY AND LARDNER LLP;SUITE 500, 3000 K STREET NW, WASHINGTON, DC, 20007, US

(73) Assignee: KABUSHIKI KAISHA TOSHIBA

(21) Appl. No.: 11/671,680

(22) Filed: Feb. 6, 2007

(30) Foreign Application Priority Data
Feb. 7, 2006 (JP) 2006-030137

(51) Int. Cl. H01L 29/76

(52) U.S. Cl. 257/379

(57) ABSTRACT

A semiconductor device according to one embodiment of the present invention includes: a semiconductor substrate; a MOSFET formed on the semiconductor substrate and which has a silicided gate electrode; and a resistance element having a resistance region formed on the semiconductor substrate, and a wiring extraction region containing therein a silicide, the wiring extraction region being formed on a wiring extraction surface of the resistance region.

### CROSS-REFERENCE TO RELATED APPLICATIONS

This application is based upon and claims the benefit of priority from prior Japanese Patent Application No. 2006-030137, filed Feb. 7, 2006, the entire contents of which are incorporated herein by reference.

### BACKGROUND OF THE INVENTION

The present invention relates to a semiconductor device and a method of fabricating the same, and more particularly to a semiconductor device having a resistance element which exists together with a metal oxide semiconductor field effect transistor (MOSFET), and a method of fabricating the same.

A semiconductor element in which a gate electrode is silicided in a fully silicided (FUSI) process for fully siliciding a polycrystalline silicon film of a gate electrode for the purpose of realizing a metal gate structure, for example, is known as one included in a conventional semiconductor device. A metallic film and a polycrystalline silicon film are fully silicided at a relatively low temperature falling in the range of about 400 to about 600° C., which makes it possible to prevent occurrence of a nonconformity that metal atoms forming the metallic film diffuse into a semiconductor substrate through a gate insulating film to be silicided. This technique, for example, is disclosed in Japanese Patent KOKAI No. 2005-243678.

A semiconductor device in which contact regions of a resistance element are silicided concurrently with formation of a semiconductor element, for example, is known as another conventional semiconductor device. With this another conventional semiconductor device, since the contact regions through which the resistance element is connected to external electrodes are silicided, an increase in contact resistance accompanying shrink of contact holes can be suppressed to a minimum, and thus an influence of the contact resistance value exerted on the entire resistance value can be controlled. This technique, for example, is disclosed in Japanese Patent KOKAI No. 10-150154.

However, the semiconductor device described in Japanese Patent KOKAI No. 10-150154 involves a problem that when the contact regions of the resistance element are silicided in the FUSI process, the resistance value of the resistance element changes due to the FUSI process and thus the highly precise resistance element cannot be made.

Also, in the resistance element having such a structure that a polycrystalline silicon film underlying a salicide block film is utilized as a resistor, during a salicide process for simultaneously siliciding a wiring extraction portion of a resistance element and a MOS gate region, a salicide reaction in the wiring extraction portion progresses not only downward, but also to a resistance region underlying the salicide block film. As a result, there is encountered a problem that the resistance value changes due to dispersion of thicknesses of the resistance elements, dispersion of reactions, dispersion of sizes of the resistance elements, and the like, which results in that a substantial length of the resistance element disperses, a difference between sizes of the resistance elements increases, dispersion of the resistance values increases, and so forth, thereby making a precision for the resistance value worse.

### BRIEF SUMMARY OF THE INVENTION

A semiconductor device according to one embodiment of the present invention includes:

a semiconductor substrate;

a MOSFET formed on the semiconductor substrate and which has a silicided gate electrode; and

a resistance element having a resistance region formed on the semiconductor substrate, and a wiring extraction region containing therein a silicide, the wiring extraction region being formed on a wiring extraction surface of the resistance region.

A method of fabricating a semiconductor device according to another embodiment of the present invention includes:

forming a gate electrode of a MOSFET by forming a polycrystalline silicon pattern on a semiconductor substrate through a gate insulating film;

forming a source region and a drain region, a channel region formed right under the gate electrode of the MOSFET through the gate insulating film being located between the source region and the drain region;

forming a resistance region having wiring extraction surfaces on the semiconductor substrate;

forming a silicide block region on the resistance region except for the wiring extraction surfaces;

forming at least one of Si epitaxial layers on the wiring extraction surfaces; and

siliciding at least one of the Si epitaxial layers and the gate electrode of the MOSFET in an FUSI process, and forming silicides on the source region and the drain region of the MOSFET, respectively.

A method of fabricating a semiconductor device according to still another embodiment of the present invention includes:

forming a gate electrode of a MOSFET by forming a polycrystalline silicon pattern on a semiconductor substrate through a gate insulating film;

forming a source region and a drain region, a channel region formed right under the gate electrode of the MOSFET through the gate insulating film being located between the source region and the drain region;

forming a resistance region having wiring extraction surfaces on the semiconductor substrate;

forming a silicide block region on the resistance region except for the wiring extraction surfaces;

forming at least one of SiGe epitaxial layers on the wiring extraction surfaces; and

siliciding at least one of the SiGe epitaxial layers and the gate electrode of the MOSFET in an FUSI process, and forming silicides on the source region and the drain region of the MOSFET, respectively.

### BRIEF DESCRIPTION OF THE DRAWINGS

FIG. 1 is a partial plan view of a semiconductor device according to a first embodiment of the present invention;

FIG. 2 is a cross sectional view of the semiconductor device according to the first embodiment of the present invention taken on a cutting plane line A-A of FIG. 1;

FIGS. 3A to 3D are respectively cross sectional views showing steps of fabricating the semiconductor device according to the first embodiment of the present invention;

FIG. 4 is a cross sectional view of a semiconductor device according to a second embodiment of the present invention taken on the cutting plane line A-A of FIG. 1; and

FIGS. 5A to 5D are respectively cross sectional views showing steps of fabricating the semiconductor device according to the second embodiment of the present invention.

### DETAILED DESCRIPTION OF THE INVENTION

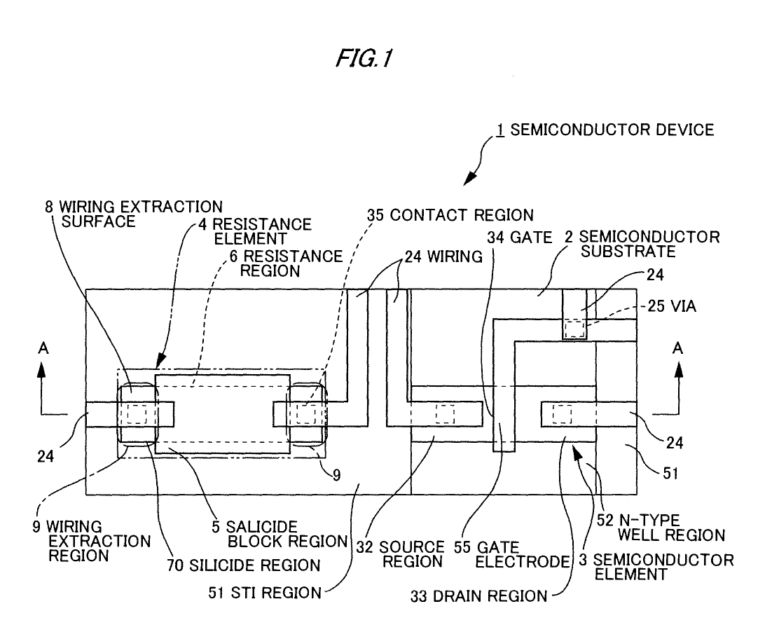

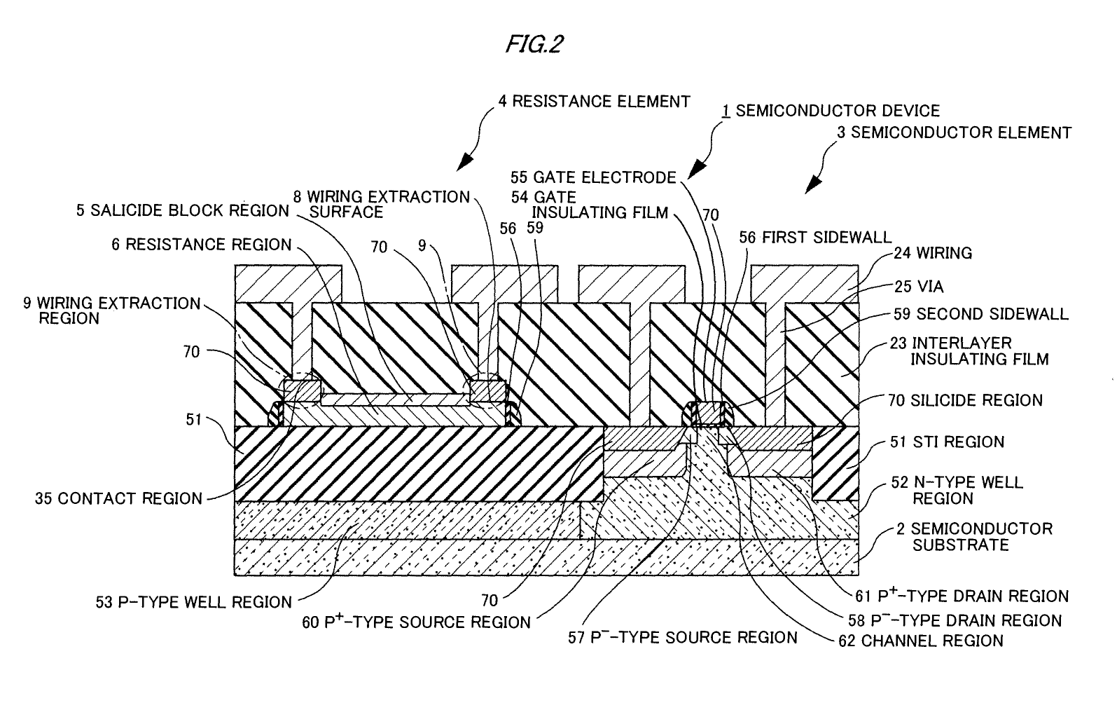

FIG. 1 is a partial plan view of a semiconductor device according to a first embodiment of the present invention. FIG. 2 is a cross sectional view of the semiconductor device according to the first embodiment of the present invention taken on a cutting plane line A-A of FIG. 1. As shown in FIGS. 1 and 2, a semiconductor device 1 of this embodiment includes a semiconductor substrate 2, a semiconductor element 3 formed on the semiconductor substrate 2, a resistance element 4 formed on the semiconductor substrate 2, and a wiring 24.

In this embodiment, a P-type silicon substrate is used as the semiconductor substrate 2.

The semiconductor element 3 is a circuit element formed on the semiconductor substrate 2 and, for example, is either a P-channel MOSFET (PMOSFET) or an N-channel MOSFET (NMOSFET). In this embodiment, the semiconductor element 3 is the P-channel MOSFET (PMOSFET), and is formed on an N-type well region 52. The semiconductor element 3 includes a source region 32, a drain region 33, a gate 34, and a gate electrode 55. The source region 32 and the drain region 33 have contact regions 35, respectively. The contact regions 35 are connected to a wiring 24 through corresponding vias 25, respectively.

The resistance element 4 is a resistance portion formed on the semiconductor substrate 2, and is formed on a shallow trench isolation (STI) region 51. The resistance element 4 includes a salicide block region 5, a resistance region 6, and silicide regions 70. The silicide regions 70 are connected to the wiring 24 through the corresponding vias 25 in contact regions 35 as upper surfaces of the corresponding silicide regions 70.

The salicide block region 5 is a block region for preventing the silicidization from progressing to a polycrystalline silicon layer formed under the salicide block region 5, and is formed in a region except for wiring extraction surfaces 8 of the resistance element 4. A tetra ethoxysilane (TEOS) film, for example, is used as a material for the salicide block region 5.

The resistance region 6 is a region functioning as a resistor, and is formed between the two silicide regions 70 on the resistance element 4 formed under the salicide block region 5. Polycrystalline silicon, for example, is used as a material for the resistance region 6.

Wiring extraction surfaces 8 are the surfaces, which are located on both sides of the salicide block region 5, of the resistance element 4, respectively, contact the silicide regions 70, and are connected to the wiring 24 through the corresponding vias 25.

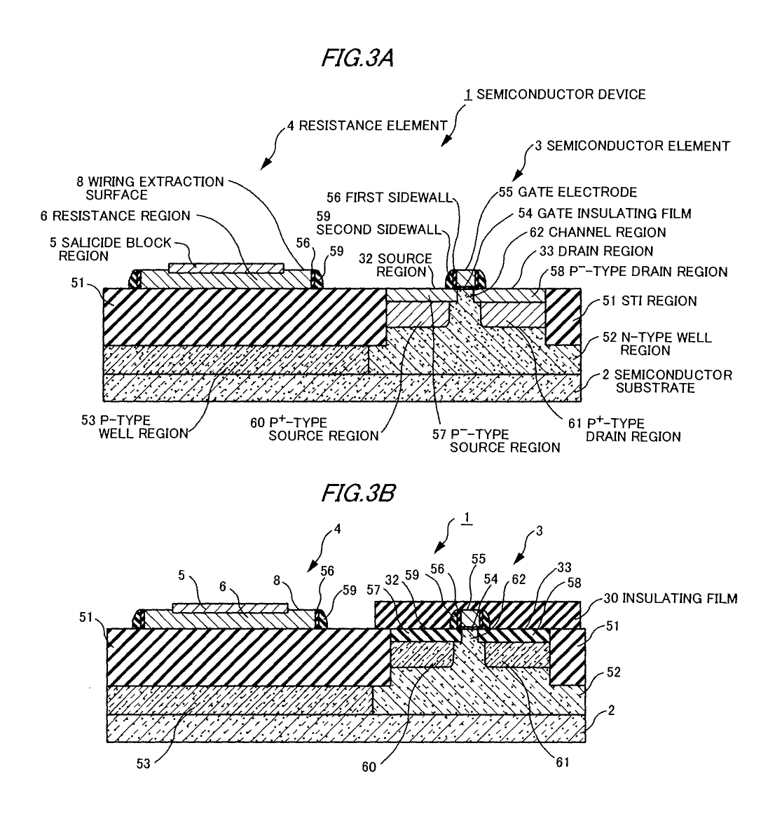

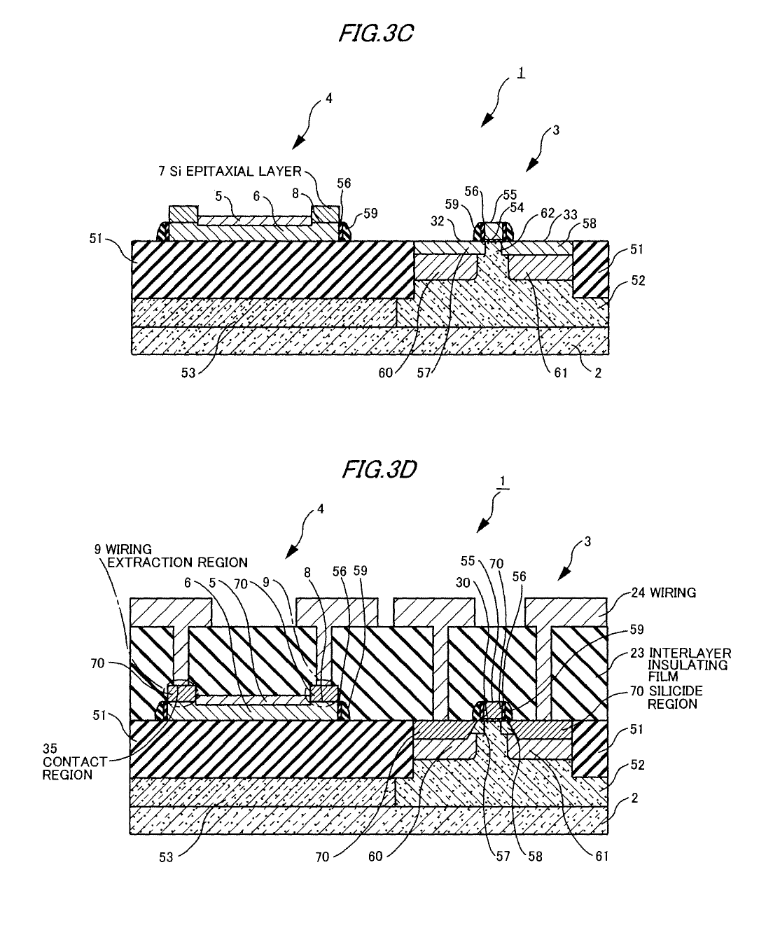

Wiring extraction regions 9 are constituted by the silicide regions 70 which are formed by siliciding Si epitaxial layers 7 (refer to FIG. 3C), respectively, and are connected to the wiring 24 through the corresponding vias 25 in the corresponding contact regions 35.

An N-type well region 52 is a region which has a given impurity concentration and which is formed on the semiconductor substrate 2 and, for example, is formed by being doped with impurity such as phosphorus.

The STI region 51 is a region formed from a buried oxide film for isolation. In this embodiment, the STI region 51 is formed on the semiconductor substrate 2 by, for example, utilizing a STI technique.

The gate electrode 55 is an electrode for controlling formation of a channel in a channel region 62 formed right under the gate insulating film 54. In this embodiment, the gate electrode 55 has a metal gate structure. The metal gate structure is formed by using an FUSI process for fully silisiding a polycrystalline silicon film.

Next, a method of fabricating the semiconductor device according to the first embodiment of the present invention will now be described in detail with reference to cross sectional views of FIGS. 3A to 3D showing fabricating processes, respectively. Here, FIGS. 3A to 3D are the cross sectional views each taken on a line A-A of FIG. 1.

FIG. 3A is the cross sectional view showing processes up to formation of the semiconductor element 3, the resistance element 4 and the like on the semiconductor substrate 2. The semiconductor device 1 in this stage is formed by using the semiconductor fabricating process utilizing the known technique.

In this embodiment, firstly, the N-type well region 52 and a P-type well region 53 are formed on the semiconductor substrate 2. Next, the STI region 51 is formed in the semiconductor substrate 2.

In a complementary metal oxide semiconductor (CMOS), the P-type well region 53 becomes a region in which an NMOSFET (not shown) is intended to be formed, and the N-type well region 52 becomes a region in which a PMOSFET is intended to be formed. In this embodiment, a description is given with respect to the case where the semiconductor element 3 is the PMOSFET. In addition, although the resistance element 4 is formed irrespective of a type of a well, in this embodiment, it is formed on the STI region 51 formed on the P-type well region 53.

Next, the gate insulating film 54 made of, for example, SiON is formed on the N-type well region 52. Next, the gate electrode 55 and the resistance region 6 are formed on the N-type well region 52 through the gate insulating film 54, and on the resistance element 4, respectively, at a time in one process by patterning a polycrystalline silicon film. The pattern of the polycrystalline silicon film is formed for formation of the gate 34 and the resistance region 6 shown in FIG. 1 in the photolithography process which is generally used.

Next, a TEOS film is formed on the semiconductor substrate 2 by, for example, utilizing a chemical vapor deposition (CVD) method, and the resulting TEOS film is then processed into a first sidewall 56 by utilizing a full surface reactive ion etching (RIE) method. Next, a P⁻-type source region 57 and a P⁻-type drain region 58 are formed by diffusing selectively P-type impurity into the N-type well region 52 so that the channel region 62 formed right under the gate electrode 55 through the gate insulating film 54 is located between the P⁻-type source region 57 and the P⁻-type drain region 58.

In addition, in the same process as that for forming the P⁻-type source region 57 and the P⁻-type drain region 58, ions of P-type impurity are selectively implanted into the semiconductor substrate 2 with a predetermined dose so that the resistance region 6 has a predetermined resistance value. In this embodiment, boron ions are implanted as the ions of the P-type impurity into the semiconductor substrate 2 with the dose of 1×10¹⁵ atoms/cm².

Next, the salicide block region 5 made of a TEOS film having a thickness of 30 nm is selectively formed on the resistance region 6 except for the wiring extraction surface 8.

Next, a film made of, for example, SiN is formed on the polycrystalline silicon surface by utilizing the CVD method or the like. The resulting film is then formed into a second sidewall 59 by utilizing the full surface RIE method. Next, a P⁺-type source region 60 and a P⁺-type drain region 61 are formed by selectively implanting ions of P-type impurity into the N-type well region 52. The P⁺-type source region 60 and the P⁻-type source region 57 constitute the source region 32, and the P⁺-type drain region 61 and the P⁻-type drain region 58 constitute the drain region 33.

Here, in order to reduce an interface resistance between each of the silicide regions 70 which will be formed in a later process and each of the wiring extraction surfaces 8, ions of P-type impurity are implanted into the resistance element 4 in the same process as that for forming the P⁺-type source region 60 and the P⁺-type drain region 61. Note that, in the case where the NMOSFET is formed as the semiconductor element 3, an N⁻-type source region and an N⁺-type source region, and an N⁻-type drain region and an N⁺-type drain region are formed at about the same time as that when a P⁻-type source region and an P⁺-type source region, and a P⁻-type drain region and an P⁺-type drain region are formed.

FIG. 3B is the cross sectional view showing a process for forming a mask material on a region in which the semiconductor element 3 is intended to be formed as a preparation for epitaxially growing silicon selectively on the wiring extraction surfaces 8 of the resistance element 4. Next, as shown in FIG. 3B, an insulating film 30 acting as the mask material for the epitaxial growth of silicon is selectively formed on the region in which the semiconductor element 3 is intended to be formed. In this embodiment, the insulating film 30 is made from, for example, a TEOS film having a thickness of 30 nm.

FIG. 3C is the cross sectional view showing a process for forming Si epitaxial layers 7 on the wiring extraction surfaces 8, respectively. As shown in FIG. 3C, since no insulating film 30 is formed on each of the wiring extraction surfaces 8 of the resistance element 4 in the preceding process, the Si epitaxial layers 7 each having a thickness of about 80 nm are formed on the wiring extraction surfaces 8 of the resistance element 4 through the selective epitaxial growth, respectively.

In this embodiment, after an epitaxial pre-treatment is carried out by using an H₂ gas, the Si epitaxial layers 7 are grown on the wiring extraction surfaces 8, respectively, in an ambient atmosphere of gases of dichlorosilane, hydrogen chloride, and B₂H₆ at 700° C. by using an LP-CVD system. Each of the epitaxial layers 7 is doped with boron ions as the impurity ions having the same conductivity type as that of the impurity ions implanted into the resistance region 6 at a concentration of 1×10²⁰ atoms/cm³. This process is carried out in order to prevent an increase in interface resistance in the silicidization in the next process. After completion of the growth of the Si epitaxial layers 7, the insulating film 30 is removed.

FIG. 3D is the cross sectional view showing processes for formation of a Ni silicide, formation of an interlayer insulating film, and formation of a wiring.

A Ni film having a thickness of 12 nm is formed over the whole surface of the semiconductor substrate 2 in a FUSI process by utilizing the sputtering method, and the resulting Ni film is made to react with the Si epitaxial layers 7 laminated on the wiring extraction surface 8, respectively, and the gate electrode 55 of the PMOSFET by performing rapid thermal annealing (RTA). As a result, the Si epitaxial layers 7 and the gate electrode 55 are Ni-silicided to turn into the silicide regions 70, respectively, and the P⁻-type source region 57 and the P⁻-type drain region 58 of the PMOSFET are made to turn into the silicide regions 70, respectively. Each of the silicide regions 70 functions as the wiring extraction region 9 since it is connected to the wiring 24 through the corresponding via 25 in the corresponding contact region 35.

After completion of the formation of the silicide regions 70, the Ni film which is left because it is not silicided is removed by carrying out the wet etching processing. It should be noted that the silicide is not limited to the Ni silicide, and thus each of the silicide regions may also contain Pt, Co, Pd, Er or the like.

Next, an interlayer insulating film 23 is deposited over the whole surface of the semiconductor substrate 2 by, for example, utilizing the CVD method, via holes in which the vias 25 are intended to be formed to the predetermined contact regions 35, respectively, are formed in the interlayer insulating film 23 by utilizing the photolithography technique, and the wiring 24 and the vias 25 are then made from a metal such as Cu. After the above-mentioned processes, the semiconductor device 1 including the semiconductor element 3, the resistance element 4, and the like is fabricated.

According to the first embodiment of the present invention, the Si epitaxial layers 7 absorb the silicide reaction which attempts to progress to the resistance region 6 underlying the salicide block region 5 of the resistance element 4. As a result, it is possible to reduce an influence of the silicide reaction exerted on the resistance value.

According to the prior art, in the FUSI process for the gate electrode of the MOSFET, since it is important to fully silicide the gate electrode in terms of the characteristics, in the gate electrode for which the heat treatment reaction is closed in the gate region in terms of the structure, the annealing conditions are determined in consideration of the sufficient reaction margin. Also, according to the conventional processes, unlike the first embodiment of the present invention, the Si epitaxial layers or the like are not laminated on the wiring extraction surfaces on the both sides of the resistance region.

For this reason, in order to reliably make the FUSI structure during the salicide process for siliciding the MOS gate region, the process conditions are determined in consideration of the dispersion of the thicknesses of the polycrystalline silicon films, the dispersion of the reactions, and the dispersion of the patterns. As a result, the reaction dispersion such as the excessive progress of the silicide reaction from the wiring extraction portion to the resistance region readily occurs in the highly precise resistance element, which causes the precision of the resistance element to be reduced.

Moreover, in the resistance element having the structure that the polycrystalline silicon film underlying the salicide block film is utilized as the resistor, during the salicide process for simultaneously siliciding the wiring extraction portion of the resistance element, and the MOS gate region, the silicide reaction in the wiring extraction portion progresses not only downward, but also to the resistance region underlying the salicide block film. Thus, the resistance value changes due to the thickness dispersion, the reaction dispersion, the resistor size dispersion, and the like, which results in the substantial length dispersion of the resistance elements. As a result, there is encountered a problem that the precision of the resistance value is made worse due to the enlargement of a difference between the sizes of the resistance elements, the increase in dispersion of the resistance values, and the like.

On the other hand, the first embodiment of the present invention adopts the structure that the Si epitaxial layers 7 are formed on the wiring extraction surfaces 8 of the resistance region, respectively. Thus, in the FUSI process for the gate electrode of the MOSFET, since the Si epitaxial layers 7 absorb the silicide reaction attempting to progress to the resistance region underlying the salicide block region 5 of the resistance element 4, it is possible to control occurrence of the reaction dispersion due to the excessive progress of the silicide reaction from the wiring extraction portion to the resistance region. Therefore, the margin in the silicidization against the fluctuation due to the thickness dispersion, the reaction dispersion, the size dispersion of the resistance elements is increased, and thus the stable resistance value is obtained for the resistance element 4 even in the FUSI process. As a result, it is possible to provide the semiconductor device which is excellent in the precision of the resistance value, and the method of fabricating the same. In particular, the dispersion of the resistance values can be reduced by increasing the substantial film thickness of the wiring extraction portion for the resistance element. As a result, it is possible to provide the semiconductor device which is excellent in the precision of the middle and high resistance values, and the method of fabricating the same.

In addition, the process for implanting the ions of the P-type impurity into the resistance element 4 in the same process as that for forming the P⁺-type source region 60 and the P⁺-type drain region 61 is provided for the interface as well between the Ni silicide and the polycrystalline silicon. Therefore, the first embodiment of the present invention has an effect that the dispersion of the resistance values is further reduced.

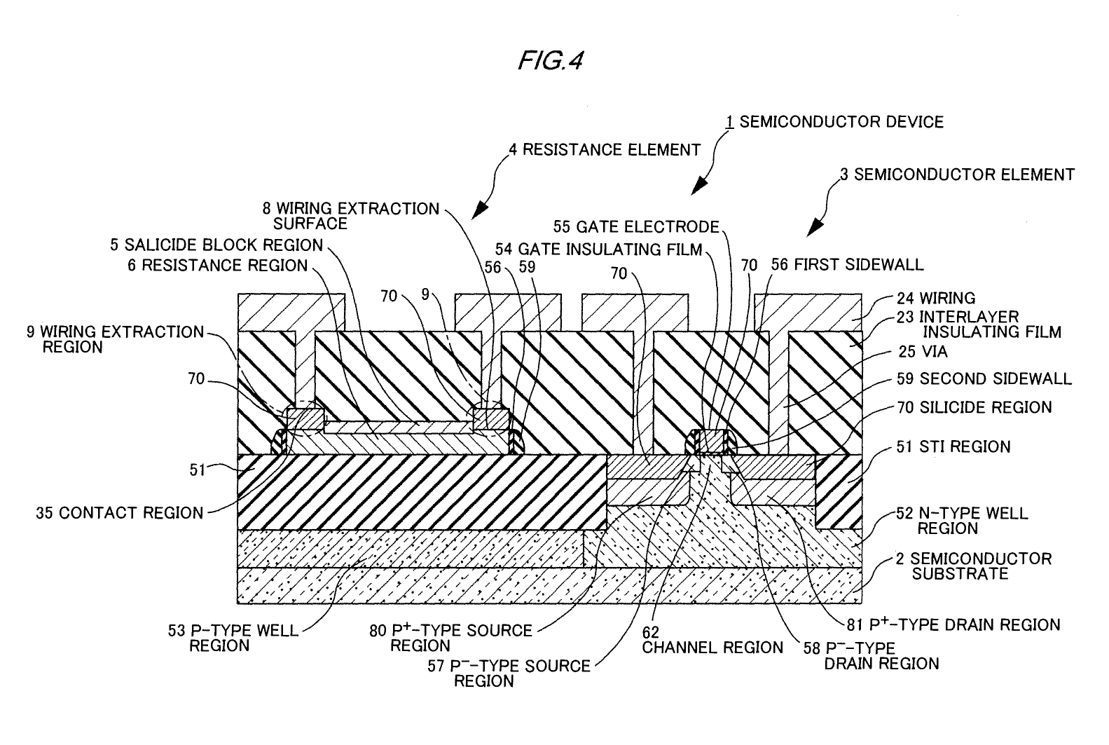

A partial plane view of a semiconductor device according to a second embodiment of the present invention is shown in FIG. 1 similarly to that of the first embodiment. FIG. 4 is a cross sectional view taken on the line A-A of FIG. 1. As shown in FIGS. 1 and 4, a semiconductor device 1 of this embodiment includes a semiconductor substrate 2, a semiconductor element 3 formed on the semiconductor substrate 2, a resistance element 4 formed on the semiconductor substrate 2, and a wiring 24.

In this embodiment, a P-type silicon substrate is used as the semiconductor substrate 2.

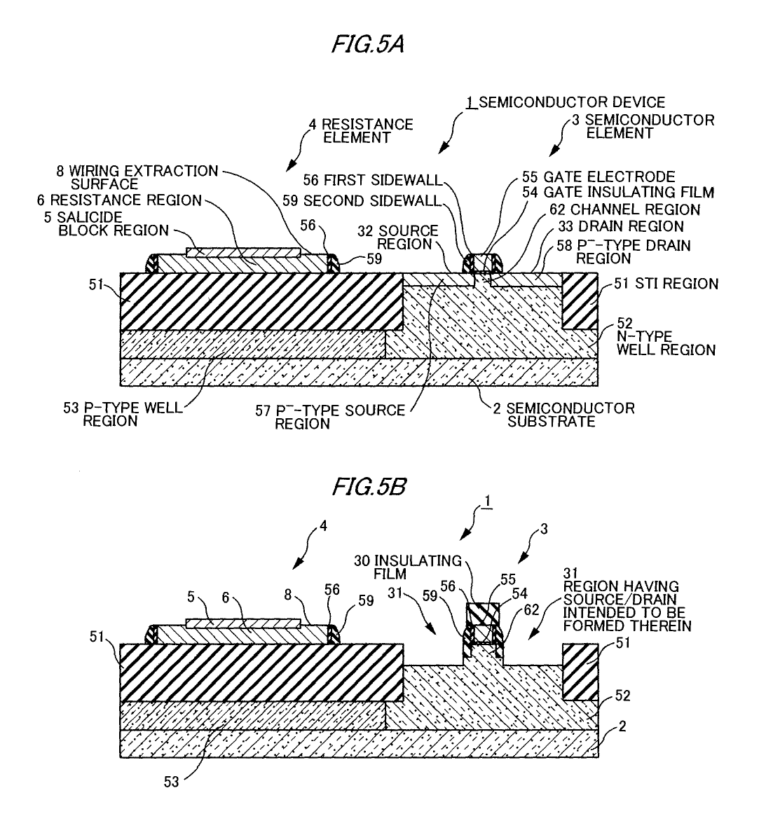

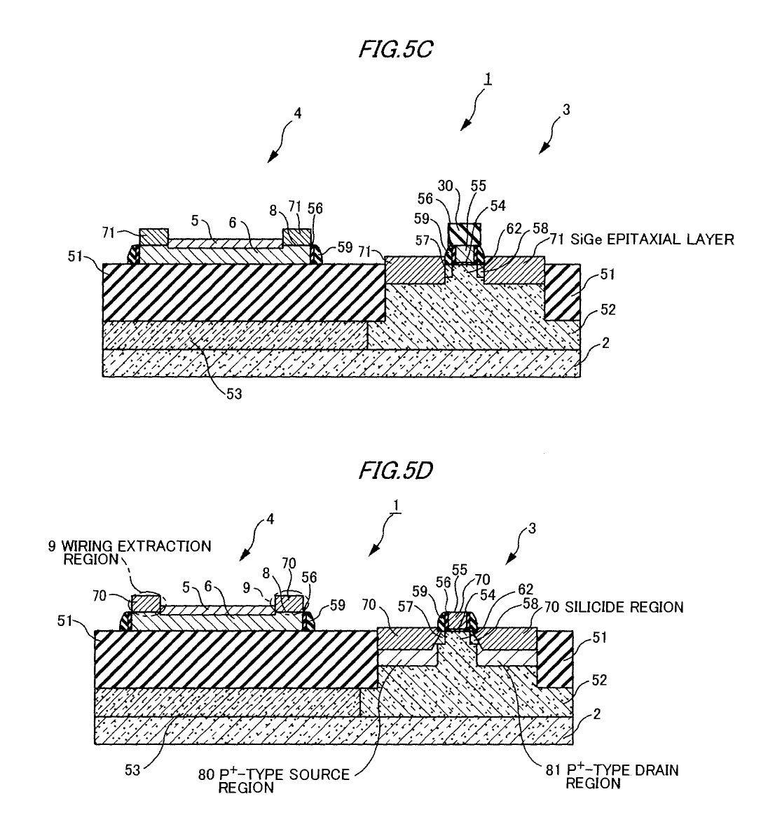

The semiconductor element 3 is a circuit element formed on the semiconductor substrate 2. In this embodiment, the semiconductor element 3 is a P-channel MOSFET (PMOSFET) and is formed on an N-type well region 12. The semiconductor element 3 includes a source region 32, a drain region 33, a gate 34, and a gate electrode 55 which are all shown in FIG. 5A. The source region 32 and the drain region 33 have contact regions 35, respectively. The contact regions 35 are connected to corresponding vias 25, respectively.

The resistance element 4 is a resistance portion formed on the semiconductor substrate 2, and is formed on an STI region 51. The resistance element 4 includes a salicide block region 5, a resistance region 6 and silicide regions 70. The silicide regions 70 are connected to a wiring 24 through corresponding vias 25 in the corresponding contact regions 35 as upper surfaces of the silicide regions 70.

The salicide block region 5 is a block region for preventing the silicidization from progressing to polycrystalline silicon layer formed under the salicide block region 5, and is formed in a region except for the wiring extraction surfaces 8 of the resistance element 4. A TEOS film, for example, is used as a material for the salicide block region 5.

The resistance region 6 is a region functioning as a resistor, and is formed between the two silicide regions 70 on the resistance element 4 formed under the salicide block region 5. Polycrystalline silicon, for example, is used as a material for the resistance region 6.

The wiring extraction surfaces 8 are the surfaces, which are located on both sides of the salicide block 5, of the resistance element 4, respectively, contact the silicide regions 70, and are connected to the wiring 24 through the corresponding vias 25.

Wiring extraction regions 9 are constituted by the silicide regions 70 which are formed by siliciding SiGe epitaxial layers 71 (refer to FIG. 5C), respectively, and are connected to the wiring 24 through the corresponding vias 25 in the corresponding contact regions 35.

An N-type well region 52 is a region which has a given impurity concentration and which is formed on the semiconductor substrate 2, and, for example, is formed by being doped with impurity such as phosphorus.

The STI region 51 is a region formed from a burried oxide film for isolation. In this embodiment, the STI region 51 is formed on the semiconductor substrate 2 by, for example, utilizing the STI technique.

The gate electrode 55 is an electrode for controlling formation of a channel in a channel region 62 formed right under the gate insulating film 54 formed in a lower portion of the gate 34. In this embodiment, the gate electrode 55 has a metal gate structure. The metal gate structure is formed by using the FUSI process for fully siliciding a polycrystalline silicon film.

Next, a method of fabricating the semiconductor device according to the second embodiment of the present invention will now be described in detail with reference to cross sectional views of FIGS. 5A to 5D showing fabricating processes, respectively. Here, FIGS. 5A to 5D are the cross sectional views each taken on the line A-A of FIG. 1.

FIG. 5A is the cross sectional view showing processes up to formation of the semiconductor element 3, the resistance element 4 and the like on the semiconductor substrate 2. The semiconductor device 1 in this stage is formed by using the semiconductor fabricating process utilizing the known technique.

In this embodiment, firstly, the N-type well region 52 and a P-type well region 53 are formed on the semiconductor substrate 2. Next, the STI region 51 is formed in the semiconductor substrate 2.

In the CMOS, the P-type well region 53 becomes a region in which an NMOSFET (not shown) is intended to be formed, and the N-type well region 52 becomes a region in which a PMOSFET is intended to be formed. In this embodiment, a description is given with respect to the case where the semiconductor element 3 is the PMOSFET. In addition, although the resistance element 4 is formed irrespective of a type of a well, in this embodiment, it is formed on the STI region 51 formed on the P-type well region 53.

Next, the gate insulating film 54 made of, for example, SiON is formed on the N-type well region 52. Next, the gate electrode 55 and the resistance region 6 each of which is made of polycrystalline silicon are formed on the N-type well region 52 through the gate insulating film, and on the resistance element 4, respectively, at a time in one process. The polycrystalline silicon film is formed in predetermined polycrystalline pattern as the gate 34 and the resistance region 6 shown in FIG. 1.

Next, a TEOS film is formed on the semiconductor substrate 2 by, for example, utilizing the CVD method, and the resulting TEOS film is processed into a first sidewall 56 by utilizing the full surface RIE method. Next, a P⁻-type source region 57 and a P⁻-type drain region 58 are formed by diffusing selectively P-type impurity into the N-type well region 52 so that the channel region 62 formed right under the gate electrode 55 through the gate insulating film 54 is located between the P⁻-type source region 57 and the P⁻-type drain region 58.

In addition, in the same process as that for forming the P⁻-type source region 57 and the P⁻-type drain region 58, ions of P-type impurity are selectively implanted into the semiconductor substrate 2 with a predetermined dose so that the resistance region 6 has a predetermined resistance value. In this embodiment, boron ions are implanted as the ions of the P-type impurity into the semiconductor substrate 2 with the dose of 1×10¹⁵ atoms/cm².

Next, the salicide block region 5 made of a TEOS film having a thickness of 30 nm is selectively formed on the resistance region 6 except for the wiring extraction surface 8.

Next, a film made of, for example, SiN is selectively formed on the polycrystalline silicon surface by utilizing the CVD method or the like. The resulting film is then formed into a second sidewall 59 by utilizing the full surface RIE method.

FIG. 5B is the cross sectional view showing a process for forming regions 31 in which the source region and the drain region are intended to be formed, respectively, by performing the etching.

An insulating film 30 becoming a mask material in a phase of Si etching in a next process is selectively formed on the gate electrode 55 of the PMOSFET. The regions 31 of the PMOSFET in which the source region and the drain region are intended to be formed, respectively, are formed by performing the Si etching by about 60 nm. In this embodiment, the insulating film 30 is made from a TEOS film having a thickness of 30 nm.

FIG. 5C is the cross sectional view showing processes for formation of the source region and the drain region, and formation of SiGe epitaxial layers on the respective wiring extraction surfaces 8 by the epitaxial growth of SiGe.

SiGe epitaxial layers 71 are formed so that each of them has a thickness of 80 nm through the selective epitaxial growth of SiGe. That is to say, the SiGe epitaxial layers 71 are formed so as to cover the exposed wiring extraction surfaces 8 of the resistance element 4 and so as to be buried in the regions 31 of the PMOSFET in which the source region and the drain region are intended to be formed, respectively. Here, the pre-treatment for the epitaxial growth similar to that in the first embodiment is carried out. In addition, in this embodiment, in order to epitaxially grow SiGe, GeH₄ is added as a gas, and an epitaxial Ge concentration is set as being about 20 atom %. This Ge epitaxial concentration must fall within the range of 10 to 30 atom %. Also, a concentration of boron doping is set as being about 1×10²⁰ atoms/cm³. After completion of the SiGe epitaxial growth, the insulating film 30 is removed.

FIG. 5D is the cross sectional view showing processes for formation of a Ni silicide, formation of an interlayer insulating film, and formation of the wiring.

Next, a P⁺-type source region 80 and a P⁺-type drain region 81 are formed by selectively implanting ions of P-type impurity into the N-type well region 52. The P⁺-type source region 80 and a P⁻-type source region 57 constitute the source region 32, and the P⁺-type drain region 81 and a P⁻-type drain region 58 constitute the drain region 33.

Here, in order to reduce an interface resistance between each of the silicide regions 70 which will be formed in a later process, and each of the wiring extraction surfaces 8, ions of P-type impurity are implanted into the resistance element 4 in the same process as that for forming the P⁺-type source region 80 and the P⁺-type drain region 81.

A Ni film having a thickness of 12 nm is formed over the whole surface of the semiconductor substrate 2 in the FUSI process by utilizing the sputtering method, and the resulting Ni film is made to react with the SiGe epitaxial layers 71 laminated on the wiring extraction surfaces 8, respectively, and the gate electrode 55 of the PMOSFET by performing the RTA. As a result, the SiGe epitaxial layers 71 and the gate electrode 55 are Ni-silicided to turn into the silicide regions 70, respectively, and the SiGe epitaxial layers 71 buried in the regions 31 of the PMOSFET in which the source region and the drain region are intended to be formed, respectively, are made to turn into the silicide regions 70, respectively. Each of the silicide regions 70 functions as the wiring extraction region 9 since it is connected to the wiring 24 through the corresponding via 25 in the corresponding contact region 35.

After completion of the formation of the silicide regions 70, the Ni layer which is left because it is not silicided is removed by carrying out the wet etching processing. It should be noted that the silicide is not limited to the Ni silicide, and thus each of the silicide regions may also contain Pt, Co, Pd, Er or the like.

Next, an interlayer insulating film 23 is deposited over the whole surface of the semiconductor substrate 2 by, for example, utilizing the CVD method, via holes in which the vias 25 are intended to be formed to the predetermined contact regions 35, respectively, are formed in the interlayer insulating film 23 by utilizing the photolithography technique, and the wiring 24 and the vias 25 are then made from a metal such as Cu. After the above-mentioned progresses, the semiconductor device 1 including the semiconductor element 3, the resistance element 4, and the like is fabricated.

According to the second embodiment of the present invention, each of the SiGe epitaxial layers buried in the PMOSFET can generate a compressive strain, thereby allowing a mobility of electric charge in the PMOSFET to be enhanced. As a result, it is possible to realize the higher performance promotion for the semiconductor element. Also, in the process for forming the SiGe epitaxial layers, the SiGe epitaxial layers 71 can be formed on the wiring extraction surfaces 8 of the resistance element 4 as well, respectively, in the same process as that for forming the source region and the drain region. As a result, it is possible to form the highly precise resistance element which exists together with the MOSFET without providing another process.

Moreover, since the SiGe epitaxial layers 71 absorb the silicide reaction attempting to progress to the resistance region 6 underlying the salicide block region 5 of the resistance element 4, it is possible to reduce the influence of the silicide reaction exerted on the resistance value. As a result, similarly to the effects of the first embodiment of the present invention, it is possible to provide the semiconductor device which is excellent in the precision of the resistance value, and the method of fabricating the same. In particular, the dispersion of the resistance values can be reduced by increasing the substantial film thickness of the wiring extraction portion for the resistance element. As a result, it is possible to provide the semiconductor device which is excellent in the precision of the middle and high resistance values, and the method of fabricating the same.

It should be noted that each of the first and second embodiments of the present invention is merely an embodiment, the present invention is not intended to be limited thereto, and the various changes thereof can be implemented without departing from the gist of the invention. In addition, the constituent elements of each of the first and second embodiments of the present invention can be arbitrarily combined with each other without departing from the gist of the invention.

What is claimed is:

1. A semiconductor device, comprising:
a semiconductor substrate;
a MOSFET formed on the semiconductor substrate and which has a silicided gate electrode; and
a resistance element having a resistance region formed on the semiconductor substrate, and a wiring extraction region containing therein a silicide, the wiring extraction region being formed on a wiring extraction surface of the resistance region.

2. A semiconductor device according to claim 1, wherein the resistance region contains therein polycrystalline silicon.

3. A semiconductor device according to claim 1, wherein the wiring extraction region are formed by a silicidization reaction between a Si epitaxial layer formed on the wiring extraction surface and a metallic film formed on the Si epitaxial layer.

4. A semiconductor device according to claim 3, wherein the metallic film contains therein at least one of Ni, Pt, Co, Pd and Er.

5. A semiconductor device according to claim 3, wherein the resistance region and the wiring extraction region contain therein impurity of the same conductivity type.

6. A semiconductor device according to claim 1, wherein the wiring extraction regions are formed by a silicidization reaction between a SiGe epitaxial layer formed on the wiring extraction surface and a metallic film formed on the SiGe epitaxial layer.

7. A semiconductor device according to claim 6, wherein the metallic film contains therein at least one of Ni, Pt, Co, Pd, and Er.

8. A semiconductor device according to claim 6, wherein a Ge concentration of the SiGe epitaxial layer is in a range of 10 to 30 atom %.

9. A semiconductor device according to claim 6, wherein the wiring extraction region, and the resistance region contain therein impurity of the same conductivity type.

10. A semiconductor device according to claim 6, wherein the MOSFET includes a source region and a drain region each having the SiGe epitaxial layer.

11. A semiconductor device according to claim 1, wherein the resistance element includes a salicide block region for blocking silicidization of the resistance region formed on the resistance region.

12. A semiconductor device according to claim 11, wherein the salicide block region contains therein TEOS.

13. A method of fabricating a semiconductor device, comprising:
forming a gate electrode of a MOSFET by forming a polycrystalline silicon pattern on a semiconductor substrate through a gate insulating film;
forming a source region and a drain region, a channel region formed right under the gate electrode of the MOSFET through the gate insulating film being located between the source region and the drain region;
forming a resistance region having wiring extraction surfaces on the semiconductor substrate;
forming a silicide block region on the resistance region except for the wiring extraction surfaces;
forming at least one of Si epitaxial layers on the wiring extraction surfaces; and
siliciding at least one of the Si epitaxial layers and the gate electrode of the MOSFET in an FUSI process, and forming silicides on the source region and the drain region of the MOSFET, respectively.

14. A method of fabricating a semiconductor device according to claim 13, wherein the siliciding of the Si epitaxial layer comprises forming a metallic film on the Si epitaxial layer and making the Si epitaxial layer and the metallic film react with each other by performing a heat treatment.

15. A method of fabricating a semiconductor device according to claim 14, wherein the metallic film contains therein at least one of Ni, Pt, Co, Pd, and Er.

16. A method of fabricating a semiconductor device, comprising:
forming a gate electrode of a MOSFET by forming a polycrystalline silicon pattern on a semiconductor substrate through a gate insulating film;
forming a source region and a drain region, a channel region formed right under the gate electrode of the MOSFET through the gate insulating film being located between the source region and the drain region;
forming a resistance region having wiring extraction surfaces on the semiconductor substrate;
forming a silicide block region on the resistance region except for the wiring extraction surfaces;
forming at least one of SiGe epitaxial layers on the wiring extraction surfaces; and
siliciding at least one of the SiGe epitaxial layers and the gate electrode of the MOSFET in an FUSI process, and forming silicides on the source region and the drain region of the MOSFET, respectively.

17. A method of fabricating a semiconductor device according to claim 16, wherein in the forming of the SiGe epitaxial layer, a Ge concentration of the SiGe epitaxial layer is set in a range of 10 to 30 atom %.

18. A method of fabricating a semiconductor device according to claim 16, wherein the siliciding of the SiGe epitaxial layer comprises forming a metallic film on the SiGe epitaxial layer and making the SiGe epitaxial layer and the metallic films react with each other by performing a heat treatment.

19. A method of fabricating a semiconductor device according to claim 18, wherein the metallic film contains therein at least one of Ni, Pt, Co, Pd, and Er.

20. A method of fabricating a semiconductor device according to claim 16, wherein the forming of the source region and the drain region comprises epitaxially growing SiGe within trenches formed in a surface of the semiconductor substrate by performing etching.
